(19) United States
(12) Patent Application Publication
(10) Pub. No.: US 2006/0156970 A1
(43) Pub. Date: Jul. 20, 2006

(54) Methods for in-situ cleaning of semiconductor substrates and methods of semiconductor device fabrication employing the same

(76) Inventors: Shin Dong-Suk, Suwon-Si (KR); Tetsuji Ueno, Suwon-Si (KR); Lee Seung-Hwan, Suwon-Si (KR); Lee Ho, ChunAnn-City (KR); Rhee Hwa-Sung, SungNam City (KR)

Correspondence Address: HARNESS, DICKEY & PIERCE, P.L.C., P.O. BOX 8910, RESTON, VA, 20195, US

(21) Appl. No.: 11/232,955

(22) Filed: Sep. 23, 2005

(30) Foreign Application Priority Data
Jan. 14, 2005 (KR) P2005-0003892

(51) Int. Cl. C30B 23/00; C30B 25/00; C30B 28/12; C30B 28/14

(52) U.S. Cl. 117/97

(57) ABSTRACT

Provided is an in-situ precleaning method for use in conjunction with epitaxial processes that utilizes temperatures at or below those typically utilized during the subsequent epitaxial deposition under pressure and ambient conditions suitable for inducing decomposition of semiconductor oxides, such as native oxides, from exposed semiconductor surfaces. The reduced temperature and the resulting quality of the cleaned semiconductor surfaces will tend to reduce the likelihood of temperature related issues such as unwanted diffusion, autodoping, slip, and other crystalline stress problems while simultaneously reducing the overall process time. The combination of pressure, ambient gas composition and temperature maintained within the reaction chamber are sufficient to decompose semiconductor oxides present on the substrate surface. For example, the reaction chamber may be operated so that the concentration of evolved oxygen within the reaction chamber is less than about 50%, or even less than 10%, of the equilibrium vapor pressure under the cleaning conditions.

### PRIORITY STATEMENT

This U.S. non-provisional application claims benefit of priority under 35 U.S.C. § 119 from Korean Patent Application No. 2005-0003892, which was filed on Jan. 14, 2005, the entire contents of which are incorporated herein by reference.

### BACKGROUND OF THE INVENTION

1. Field of the Invention

The present invention relates to the field of fabrication of semiconductor devices, particularly processes including the formation of epitaxial layers on a silicon surface and processes for cleaning the silicon surfaces prior to the formation of the epitaxial layer.

2. Background Art

In the fabrication of semiconductor devices on silicon wafers, various structures such as gate electrode structures, channels, interlayer insulating layers, etc. are formed on a silicon substrate. The quality of the semiconductor devices produced by these fabrication processes is closely related to the series of individual processes by which the various structures are formed. One factor in the quality of the resulting semiconductor devices is the cleanliness of the substrate surface on which the various structures are grown, formed or deposited.

Continued advances in decreasing the size of the various circuit elements formed on the semiconductor substrate have, in turn, tended to necessitate more stringent control of impurities and contaminants in the processing chambers and on the surfaces of the semiconductor devices. With circuit elements well under one micron in size, even minute quantities of one or more contaminants can significantly reduce the yield of wafers and/or degrade the reliability of the resulting semiconductor devices.

One contaminant of particular concern is silicon oxide (SiOₓ) formed on a bare silicon surface prior to the deposition of another layer or the growth of an epitaxial layer. This silicon oxide can be true “native oxide” that results from exposing a bare silicon to an oxidizing ambient, i.e., oxygen and water vapor in the air, even at room temperatures or “chemical oxide” that is produced during wafer processing, for example through the reaction of oxidizing species within a reaction chamber as wafers are ramping up to a deposition temperature. Native oxide typically forms on exposed silicon wafer surfaces during processing steps which expose the wafer to ambient conditions, particularly the wet cleaning steps commonly used to prepare the surface for a deposition process. This oxidation can be exacerbated by batch loads into single-wafer processes where the cleaned wafers are exposed to ambient conditions as other wafers are being processed through the equipment. Further, because each of the successive wafers to be loaded into the processing equipment has been exposed to the oxidizing ambient for a different period of time, the degree of oxidation will vary throughout the batch from which the integrated circuit structures were formed.

It is therefore desirable that prior to the deposition or growth of any subsequent material layer on a silicon substrate, the surface of the substrate, particularly exposed semiconductor surfaces, be substantially or completely free of contaminants such as native oxide and other impurities. Successful preparation of the substrate surface will remove those contaminants that could be trapped at the interface between the substrate surface and the layer being formed or grown on the substrate, thereby improving the electrical properties of the resulting semiconductor devices and/or improving the reliability.

It has been observed that the growth of epitaxial silicon films on a silicon substrate can be affected by the presence of native oxide or other contaminants present on the silicon surface. The effects can include retarded growth of the epitaxial layer in those regions of the silicon surface on which native oxide is present and/or stacking or dislocation faults within the resulting single crystal epitaxial layer and/or result in polycrystalline epitaxial regions that will tend to degrade the electrical properties of the epitaxial layer and, consequently, the performance and/or reliability of the resulting semiconductor devices. The formation of native oxide and the presence of various contaminants on the silicon surface becomes an increasingly serious problem as device geometries continue to shrink by degrading process control and layer uniformity during semiconductor device fabrication processes.

Therefore, any native oxide film or other contaminant(s) should be removed before deposition and/or growth of various films necessary for the fabrication of the semiconductor devices. This is particularly true with respect to the exposed silicon surfaces on which epitaxial silicon layers are to be formed. Conventional cleaning methods use the process chamber of a chemical vapor deposition (CVD) reactor for both cleaning the wafer surface and the subsequent wafer processing, e.g., the formation of an epitaxial silicon layer on the wafer.

One conventional method is commonly referred to as a hydrogen bake. As the name implies, this method uses hydrogen gas to reduce the native silicon oxide by removing the oxygen to form water and leaving the silicon on the surface. During the hydrogen bake process, the substrate heated to a relatively high temperature, e.g., 850-1200° C. while hydrogen gas flows into the chamber and across the substrate. These hydrogen bake conditions are maintained for a period deemed sufficient to remove substantially all of the native oxide from the silicon surface, thereby preparing a clean silicon surface for the subsequent epitaxial deposition. At the conclusion of the hydrogen bake process, the chamber and the substrate must typically be cooled to a temperature more suitable for the epitaxial silicon deposition.

Another conventional cleaning method involves an HCl etch, frequently in conjunction with the hydrogen bake process detailed above. The HCl etch method also typically includes placing the substrate in the reaction chamber and heating the substrate to a relatively high temperature, e.g., 850-1200° C. or more under a mixed flow of HCl and H₂, e.g., 1-5% HCl in H₂, to remove damaged silicon and metal contamination remaining on the substrate surface after previous processes, for example chemical mechanical polishing (CMP). This HCl etch process is maintained for a period deemed sufficient to remove substantially all of the native oxide and damage from the silicon surface, thereby preparing a clean silicon surface for the subsequent epitaxial deposition. Again, however, at the conclusion of the HCl etch process the chamber and the substrate must typically be cooled to a temperature more suitable for the epitaxial silicon deposition.

As noted above, these conventional cleaning or deposition preparation techniques require that the substrate be brought to a relatively high temperature in the epitaxial deposition process chamber. The temperatures typically utilized for both the hydrogen bake and HCl etch processes are substantially higher than the temperatures typically employed during epitaxial silicon deposition. Indeed, the high temperatures utilized during the cleaning processes tend to decrease the mechanical strength of silicon wafers, increasing the likelihood of forming slip defects which can lead to yield loss and reliability issues.

The high temperatures also increase the risk of increased diffusion from previously formed n-type and p-type regions into adjacent but more lightly doped regions, thereby degrading the junction formed between the differently doped regions. Depending on the nature of the exposed regions, the high temperatures may also increase the risk of undesirable autodoping whereby at the cleaning temperature one or more dopants from heavily doped regions evaporate from the substrate and deposit on the chamber walls and/or other regions of the substrate. During the subsequent formation of a lightly-doped epitaxial layer, these previously evaporated dopants may contaminate the epitaxial layer, thereby producing undesirable and unpredictable changes in the dopant concentration in the epitaxial layer.

Another disadvantage associated with the conventional cleaning methods detailed above is reduced throughput through the process chamber resulting from a combination of the actually cleaning process and the need to adjust the temperature of the chamber and the substrate before the epitaxial deposition can be initiated. Throughput can be increased by adding more process chambers to the system but process chambers tend to be expensive and would consume more clean-room floor space, increasing both the capital investment and operating costs for the system.

There remains a need, therefore, for an in-situ cleaning process for epitaxial deposition process that will improve process throughput and the quality and uniformity of the resulting semiconductor devices.

### BRIEF SUMMARY OF THE INVENTION

The invention provides an in-situ precleaning method that utilizes temperatures below those typically utilized during the subsequent epitaxial deposition and substantially below the temperatures used in prior cleaning methods, thereby reducing the likelihood of temperature related issues including, for example, unwanted diffusion, autodoping, slip, and other stress problems while simultaneously reducing the overall process time.

The reduced temperature used for cleaning and removing contaminants from silicon surfaces prior to epitaxial silicon deposition of silicon will reduce the thermal budget of the fabrication process and tend to maintain the functional dimensions and performance of the CMOS structures previously formed on the substrate.

The combination of pressure and temperature maintained within the reaction chamber are sufficient to evaporate silicon dioxide from the substrate surface. The pumps and/or carrier gas(es) introduced into the reaction chamber will generally be sufficient to remove silicon dioxide vapor from the chamber thereby preventing an equilibrium condition from being reached. In particular, the reaction chamber will generally be operated whereby the concentration of silicon dioxide vapor within the reaction chamber is less than about 50%, or even less than 10%, of the equilibrium vapor pressure under the cleaning conditions. As will be appreciated, shifting the reaction in favor of evaporation by further reducing the partial pressure of the silicon dioxide vapor within the reaction chamber will tend to increase the evaporation rate accordingly.

Example embodiments of the invention include methods of fabricating an epitaxial layer comprising, placing a substrate having an exposed semiconductor surface into a reaction chamber; establishing a cleaning pressure in the reaction chamber and heating the substrate to a cleaning temperature to establish a cleaning condition under which oxide present on the exposed semiconductor surface will decompose and release oxygen gas; maintaining the cleaning condition for a cleaning period sufficient to remove the oxide, thereby forming a clean semiconductor surface; forming an epitaxial layer on the clean semiconductor surface; and removing the substrate from the reaction chamber. A cleaning period of less than about 200 seconds would typically be sufficient to remove native oxides from semiconductor surfaces using a cleaning pressure of less than about 50 mTorr with a cleaning temperature of less than about 800° C. As used herein, the term “about” is intended to encompass certain variations attributable to the capability of the particular apparatus and/or associated equipment being used to practice the recited method to control and/or measure one or more parameters. For example, heating equipment set for 800° C. will typically not be able to maintain that precise temperature, but will normally exhibit some degree of variation, both higher and/or lower, about the set point. Accordingly, the use of the term “about” simply recognizes these expected variations and indicates that such normal variations are to be considered within the scope of the claimed parameter.

Optionally, a carrier gas, for example hydrogen, argon, neon, krypton and mixtures thereof, can be injected in to the reaction chamber during at least a portion of the in-situ cleaning process. The combination of maintaining a vacuum condition in the reaction chamber and/or injecting a carrier gas into the reaction chamber during the in-situ cleaning process should be sufficient to reduce the partial pressure of semiconductor oxide vapor within the reaction chamber to below the equilibrium value for the temperature and pressure being utilized. If utilized, however, the carrier gas will typically be injected into the reaction chamber at a rate well below that typically used in for hydrogen baking or etching processes in similarly sized reaction chambers. For example, if H₂ is used as a carrier gas, the flow rate may be less than about 25%, or possibly less than about 10% of the flow rate that would have been utilized in a conventional hydrogen baking process.

It is anticipated that reducing the partial pressure of the oxygen gas to no more than about 50% and perhaps no more than about 10% of the equilibrium value will enhance the decomposition of the semiconductor oxides and reduce the processing time required to obtain a cleaned semiconductor surface. As will be appreciated, the potential evaporation of other materials exposed on the surface of the semiconductor substrate will need to be taken into consideration in order to ensure that the oxide is removed without causing erosion or damage to other device structures and will guide the selection of appropriate temperature and pressure parameters. As detailed below, the in-situ cleaning process is not limited to silicon surfaces but may be utilized for other semiconductor surfaces including, for example, germanium, binary semiconductor materials, for example silicon/germanium and silicon carbide, tertiary semiconductor materials, quaternary semiconductor materials and combinations thereof.

Example embodiments of the invention include methods of fabricating semiconductor devices including processing a semiconductor substrate to form intermediate device structures having exposed semiconductor surfaces; placing the intermediate device structures into a reaction chamber; establishing a cleaning pressure in the reaction chamber and heating the intermediate device structures to a cleaning temperature to establish a cleaning condition under which oxide present on the exposed semiconductor surfaces will decompose and release oxygen gas; maintaining the cleaning condition for a cleaning period sufficient to remove the oxide, thereby forming clean semiconductor surfaces; forming an epitaxial layer on the clean semiconductor surfaces; and removing the semiconductor substrate from the reaction chamber. The exposed semiconductor surfaces can include, for example, source/drain regions and/or gate electrode surfaces and the epitaxial layer structure may include single crystal semiconductor structures, polycrystalline semiconductor structures, amorphous semiconductor structures and combinations thereof.

Example embodiments of the invention include methods of fabricating epitaxial layers comprising placing a substrate having an exposed semiconductor surface into a reaction chamber; establishing a cleaning pressure in the reaction chamber and heating the substrate to a cleaning temperature under a cleaning ambient to establish a cleaning condition under which a major portion of oxide present on the exposed semiconductor surface will be removed by decomposition and a minor portion of the oxide present on the exposed semiconductor surface will be converted to silicon by a reduction reaction; maintaining the cleaning condition for a cleaning period sufficient to remove the oxide, thereby forming a clean semiconductor surface; forming an epitaxial layer on the clean semiconductor surface; and removing the substrate from the reaction chamber.

In some instances, the method of forming an epitaxial layer may include establishing a first cleaning pressure in the reaction chamber and heating the substrate to a first cleaning temperature under a first cleaning ambient to establish a first cleaning condition under which a major portion of oxide present on the exposed semiconductor surface will be removed by decomposition and then establishing a second cleaning pressure in the reaction chamber and heating the substrate to a second cleaning temperature under a second cleaning ambient to establish a second cleaning condition under which a minor portion of oxide present on the exposed semiconductor surface will be converted to silicon by a reduction reaction; maintaining the second cleaning condition for a second cleaning period sufficient to convert the minor portion of the oxide, thereby forming a clean semiconductor surface; forming an epitaxial layer on the clean semiconductor surface; and removing the substrate from the reaction chamber.

Example embodiments of the invention include methods of cleaning exposed semiconductor surfaces comprising establishing a cleaning pressure in a reaction chamber and heating a semiconductor substrate to a cleaning temperature of under a cleaning ambient to establish a cleaning condition under which a major portion of oxide present on the exposed semiconductor surface will be removed by decomposition. This decomposition step may be performed in conjunction with a reduction step that will remove the remaining minor portion of the oxide present on the exposed semiconductor surface. Again, however, the semiconductor cleaning methods will typically utilize a cleaning temperature of no more than about 800° C. while maintaining conditions within the reaction chamber that will promote the decomposition of the undesirable semiconductor oxides from the exposed semiconductor surfaces.

### BRIEF DESCRIPTION OF THE DRAWINGS

The invention will become more apparent by describing in detail exemplary embodiments thereof with reference to the attached drawings in which:

FIG. 1 illustrates an example process flow according to an embodiment of the invention;

FIG. 2 illustrates an example of a reaction chamber in which methods of in-situ cleaning according to the invention may be conducted;

FIGS. 3A-3D illustrate selected process steps in an example process flow according to an embodiment of the invention;

FIG. 4 is a chart illustrating improvement in the Vₜₕ obtained in transistors manufactured using example and comparative process flows;

FIGS. 5A and 5B illustrate a top view and a cross-sectional view of a gate structure manufactured using a conventional process flow; and

FIGS. 6A and 6B illustrate a top view and a cross-sectional view of a gate structure manufactured using an example process flow according to an embodiment of the invention.

These drawings have been provided to assist in the understanding of the exemplary embodiments of the invention as described in more detail below and should not be construed as unduly limiting the invention. In particular, the relative spacing, positioning, sizing and dimensions of the various elements illustrated in the drawings are not drawn to scale and may have been exaggerated, reduced or otherwise modified for the purpose of improved clarity.

Those of ordinary skill in the art will also appreciate that a range of alternative configurations have been omitted simply to improve the clarity and reduce the number of drawings. Those of ordinary skill will appreciate that certain of the various process steps illustrated or described with respect to the exemplary embodiments may be selectively and independently combined to create other methods useful for manufacturing semiconductor devices without departing from the scope and spirit of this disclosure.

### DETAILED DESCRIPTION OF EXAMPLE EMBODIMENTS

In order to grow higher quality epitaxial silicon on the exposed silicon surfaces of a semiconductor substrate, the exposed silicon surfaces should be as near as possible to a perfect crystal surface. In particular, processes and procedures should be utilized to remove contamination from silicon surfaces that are also substantially free of surface irregularities such as pits or other crystal defects to avoid compromising the resulting crystalline lattice structure formed during the subsequent epitaxial process. For example, physical contaminants such as oxides, metals and/or organics on the starting silicon surface will tend to produce defective epitaxial material having a variety of crystalline defects.

As will be appreciated, an epitaxial layer comprising something less than a regular single crystalline lattice will tend to degrade the yield of the fabrication process, device performance and/or device reliability. For example, defects associated with contamination may cause the wafer to fail in-line quality checks and inspections during the fabrication process resulting in fewer wafers completing the fabrication process and higher costs due to lower wafer yield. Device performance can be changed, for example, by unwanted mobile ionic contaminants resulting in a device unsuitable for the use for which it was designed, resulting in lower chip yield. Similarly, device reliability can be adversely affected, for example, by even small levels of metallic contamination which can migrate through the device structures and eventually cause device failure. Therefore, it is important to control the presence of contaminants and surface irregularities on the silicon surface in order to improve the epitaxial silicon layers and reduce or prevent adverse effects on yield, performance, and reliability of the resulting semiconductor devices.

The types of contaminants which must be removed from the silicon surface may include, for example, particulate matter,.organic residue, and inorganic residue. Particulate matter may include dust and smoke particles, as well as other impurities commonly found in the air, and bacteria that grow in water systems and on surfaces not cleaned regularly. Organic residues tend to be associated with compositions that include organic chemical compounds containing carbon, for example, oils in fingerprints, photoresists used during previous photolithography processes or compounds included in CMP slurry compositions. Inorganic residues are associated with chemical compounds that do not include carbon; for example, hydrochloric acid or hydrofluoric acid introduced during previous steps in the wafer fabrication process or oxides resulting from exposure of unprotected silicon surfaces to an oxidizing ambient. As these examples indicate, the sources of contamination include materials which are generally inescapable in, the environment, such as carbon and oxygen, but also encompass materials used or generated during other steps in the fabrication process, for example, chemical residue on CVD reactor walls or residual oxides from typical cleaning solvents such as peroxides.

One method for cleaning the wafer surface prior to epitaxial deposition processes is to employ a sequence of heated, peroxide-charged hydrochloric acid and. ammonia hydroxide baths. Very harsh solvents can be used because the silicon surface is extremely resistant to almost all acids and bases. However, as noted above, the base, silicon surface will almost immediately react with and bind to impurities that are always present in both the air and in aqueous solutions. By way of contrast, a fully oxygenated silicon surface (i.e., glass or SiO₂) is relatively inert. Prior to subsequent epitaxial deposition, the protective silicon oxide and any residual contaminants must be removed from the silicon surface.

As also noted above, performing this surface cleaning in-situ, i.e., in the same reaction chamber that will subsequently be used for forming the epitaxial layer can be used to provide a clean unoxidized silicon surface for the epitaxial process. However, as also noted above, performing the conventional surface cleaning typically involves heating the substrate to temperatures at or above 850° C. and perhaps as high as 1200° C. While these higher temperatures may be effective for providing a suitably clean surface, they also carry with them the risk of crystalline damage and can represent a significant contribution to the overall thermal budget of the final semiconductor device. As the device geometries continue to shrink, fabrication processes must meet ever more stringent requirements for thermal budget in order to avoid compromising the CMOS electrical characteristics of the resulting devices. In particular, threshold voltage (Vₜₕ) is a key device parameter and is quite sensitive to excess dopant diffusion that can result from excessive heating during device fabrication.

### FIRST EXAMPLE EMBODIMENT

Although the examples described below will, for convenience, refer to semiconductor substrates having silicon surfaces, the invention is not so limited and may be applied to a variety of substrates including, for example, single crystal silicon substrates, silicon on insulation (SOI) substrates having single crystalline silicon, single crystal silicon-germanium substrates. Other potential substrates include single crystal germanium substrates and single crystal silicon-carbide substrates as well as a variety of tertiary and quaternary semiconductors including, for example III-IV and II-V semiconductor compounds such as AlₓIn_{y}Ga₁₋ₓN and other semiconductor compounds known to those of ordinary skill in the art.

The cleaning methods according to the invention may be utilized with both unprocessed substrates and processed substrates that have already completed a substantial portion of the fabrication process. The processed substrates may already include a variety of circuit structures including wells, source/drain regions, junctions, gate electrode structures and a variety of dielectric and conductive layers arranged in functional relationships to one another. Regardless of the degree of processing to which the substrate has previously been subjected, each of the substrates will also include at least some regions in which a silicon surface is exposed for the epitaxial growth of a single crystal semiconductor layer.

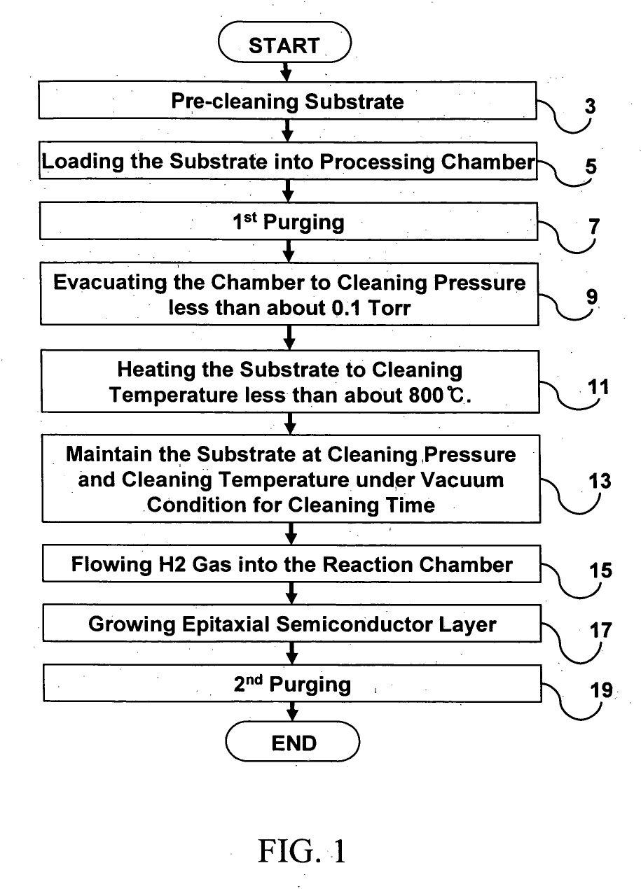

As illustrated in the flowchart provided in FIG. 1, an initial step will involve a precleaning process 3 that will be completed before the substrate is placed in the reaction chamber. This precleaning process is intended to remove the bulk of the native oxide and any other contaminants using a combination of wet and/or dry cleaning methods. Oxidizing solutions such as those employed in conventional RCA and/or piranha (H₂O₂/H₂SO₄) wet cleaning processes may be utilized to remove organic and/or inorganic contaminants from the surface.

A conventional RCA clean includes 1) removing insoluble organic contaminants using a 5:1:1 H₂O:H₂O₂:NH₄OH solution; 2) removing native oxide and some metallic contaminants, using a diluted 50:1 H₂O:HF solution; and 3) removing ionic and heavy metal atomic contaminants using a solution of 6:1:1 H₂O:H₂O₂:HCl. As will be appreciated, certain steps of these wet processes may be replaced or supplemented with dry etch processes and mechanical scrubbers and/or rinses may be employer to reduce particulates on the substrate surface. However, as noted above, although most, if not all, of the native oxide layer will be removed in the HF solution or a buffered HF (BHF) solution, a bare silicon surface is highly reactive and will tend to oxidize at least partially during the rinsing and drying steps utilized to remove the various chemicals applied to the surface. Accordingly, there remains a need for an in-situ clean prior to depositing the epitaxial layer.

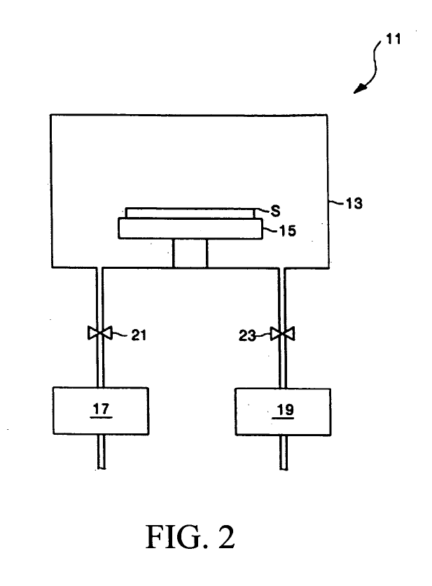

As illustrated in FIGS. 1 and 2, after the substrate S has been precleaned, in step 5 the substrate can be placed in an apparatus 11 including a processing or reaction chamber 13 through a load lock (not shown) utilizing one of a variety of movement and positioning mechanisms (not shown) well known to those of ordinary skill in the art. Within the chamber 13, the substrate S can be supported on a chuck assembly 15 that can also be configured for positioning the substrate at various vertical positions depending on the configuration of the reaction chamber, the gas injection apparatus and the manner in which power is applied to the reaction gas within the chamber.

As illustrated in FIG. 2, the reaction chamber 13 will be connected with one or more vacuum pumps with a typical configuration including a high vacuum pump 17, for example a turbo molecular pump capable of reducing the pressure within the reaction: chamber to a pressure of about 10⁻¹⁰ Torr, in combination with a rough pump 19 capable of removing a larger volume of gas from the reaction chamber to establish a pressure within reaction chamber of about 10⁻³Torr. Each of the pumps may be connected to the reaction chamber 13 through dedicated exhaust line controlled by one or more valves 21, 23.

Once the substrate S is properly positioned on the chuck assembly 15, also sometimes referred to as a platen or wafer supporter, an initial evacuation of the gas from within the reaction chamber 13 can be conducted with the rough pump to reduce the pressure within the reaction chamber for step 7 of FIG. 1, the first purging step. The first purging step may be initiated when the pressure within the reaction chamber is still relatively high, e.g., about 100 Torr with the introduction of hydrogen gas into the reaction chamber although lower pressures would also be suitable. The combination of the hydrogen gas being introduced into the reaction chamber and the vacuum pump continuing to remove gas from the reaction chamber will substantially remove any residual nitrogen, oxygen and water vapor that was initially present in the reaction chamber.

During this first purging step, particularly after the majority of the oxidizing species have been removed from the reaction chamber and the ambient is relatively pure hydrogen, the chamber and the substrate S may be heated to a standby temperature within, for example, a range of about 300° C. to about 600° C. As the first purging step is completed, the flow of hydrogen gas is terminated and the high vacuum pump 17 is engaged to further reduce the pressure within the reaction chamber.

The pressure within the vacuum chamber 13 will then be reduced from the first purging pressure to a cleaning pressure within a range from about 10⁻⁹ Torr to about 10⁻¹ Torr, during step 9 of FIG. 1, although more narrow ranges and relatively higher pressure ranges, e.g., 10⁻⁶ to 10⁻¹ Torr or 0.1-50 mTorr are expected to be suitable for practicing the invention. This cleaning pressure will be established and maintained within the reactor chamber using a combination of the rough and high vacuum pumps throughout the cleaning step. The cleaning pressure selected will also be a function of the cleaning temperature whereby the undesirable semiconductor oxides, in this instance silicon oxide, will start to decompose, i.e., releasing oxygen gas from the oxide without resulting in excessive silicon losses from the exposed silicon surfaces.

Once the cleaning pressure has been established within the reaction chamber 13, the substrate S, and typically the other components of the reaction chamber within which the substrate resides will be heated to a cleaning temperature of less than about 800° C. but sufficient to obtain a satisfactory rate of evaporation of the undesirable semiconductor oxides from the surface of the substrate S, step 11 of FIG. 1. With respect to the cleaning temperature, although the cleaning temperature should typically not exceed about 800° C., lower temperatures, for example from about 600° C. to about 700° C., are expected to be satisfactory.

Although no additional gas need be introduced into the reaction chamber 13 during the cleaning step, a relatively low flow rate of hydrogen or an inert gas, for example argon, neon, xenon, krypton and mixtures thereof, may be introduced into the reaction chamber as a carrier gas. The optional carrier gas introduction may be used for establishing a gas flow through the chamber that will tend to improve the removal of the oxygen released from the oxides within the reactor and/or suppress unwanted reactions at the cleaned surface of the substrate S. The combination of the pumps and the optional introduction of a carrier gas should generally be sufficient to maintain a concentration of oxygen gas within the reaction chamber at less than about 50% of a saturation amount under the particular cleaning conditions.

Although hydrogen may be used for this purpose, the amount of hydrogen being introduced and the temperature at which the hydrogen is being introduced are well below those generally considered sufficient to achieve the reduction of silicon dioxide associated with the conventional hydrogen bake processes. For example, for a given reaction chamber the sub-purge introduction of hydrogen into the reactor chamber may be at a level of less than about 10%, or even less than about 3%, of the hydrogen flow rates utilized during conventional hydrogen bake processes.

The cleaning pressure and cleaning temperature are maintained within appropriate ranges for a cleaning period sufficient to remove substantially all evaporating contaminants from the substrate surface including, for example, oxygen from decomposing native oxides, step 13 of FIG. 1. Depending on the cleaning temperature, the cleaning pressure and the configuration of the substrate being cleaned with respect to the amount of exposed silicon and the degree of contamination, particularly by native oxides, the cleaning time may vary between about 10 seconds and 500 seconds. In most instances, it is anticipated that a cleaning time between about 30 seconds and 120 seconds, for example, about 60 seconds, will be sufficient to achieve the desired cleaning. In the event that this cleaning time is not sufficient, it is anticipated that those of ordinary skill in the art will be capable of adjusting the cleaning time, cleaning pressure and/or cleaning temperature as needed to obtain the desired degree of oxide removal from the substrate.

We also note that the introduction of the hydrogen gas, step 15 of FIG. 1, or other inert gases may be delayed until the cleaning step has been essentially completed under vacuum conditions, typically under a reactor chamber pressure of less than about 10⁻³ Torr. The hydrogen may be introduced to further prepare the silicon surfaces for the subsequent in situ silicon epitaxial process. The temperature of the substrate can then be adjusted as needed to establish the epitaxial process conditions within the reactor chamber, preferably to a temperature relatively close to the cleaning temperature. By using a cleaning temperature relatively close to that of the epitaxial temperature, the utilization of the reactor may be increased by avoiding the tedious ramping and adjusting associated with larger temperature differentials.

After the substrate S has been adjusted to the appropriate temperature for the growth of the epitaxial semiconductor layer, additional reaction gases, for example silicon source gases such as SiH₄ and SiH₂Cl₂, or germanium source gases such as GeH₄ and GeH₂Cl₂ and/or other semiconductor source gases may be introduced into the reaction chamber under the pressure, temperature, power and bias settings sufficient to cause an epitaxial layer to form on the exposed semiconductor surface(s) in the same reaction chamber previously used to clean the exposed semiconductor surfaces.

As will be appreciated, if the substrate has not been subjected to any of the semiconductor fabrication processes that would have produced patterns of conducting, insulating and semiconducting materials on the original substrate, the epitaxial layer will be formed on the entire surface of the wafer. Conversely, when the substrate has previously been subjected to some degree of semiconductor device fabrication processing, the processed wafer will include some patterns of insulating or conducting materials that expose regions of the semiconductor substrate, the epitaxial layer will be selectively grown only on the exposed silicon surface and/or on the exposed polysilicon surfaces including, for example, gate polysilicon.

The epitaxial layer need not be identical to the surface on which it is being formed or grown. Indeed, the introduction of the appropriate quantities of certain alloying elements will tend to produce stronger and/or more flexible or ductile material. With regard to semiconductors, this technique may be used for the production of strained lattice materials and/or tertiary and quaternary semiconducting materials such as AlGaN, InGaN, AlInGaN and AlPGaN.

Once the cleaning and reaction steps have been completed, the reactor chamber may be subjected to a second purging step which involves the reintroduction or continued introduction of hydrogen gas or one or more inert gases into the reaction chamber as the substrate is cooled from the epitaxial deposition temperature. Introducing hydrogen or another inert gas during this cooling process will tend to suppress or prevent undesirable reactions as the substrate is cooled before being removed from the reaction chamber.

### SECOND EXAMPLE EMBODIMENT

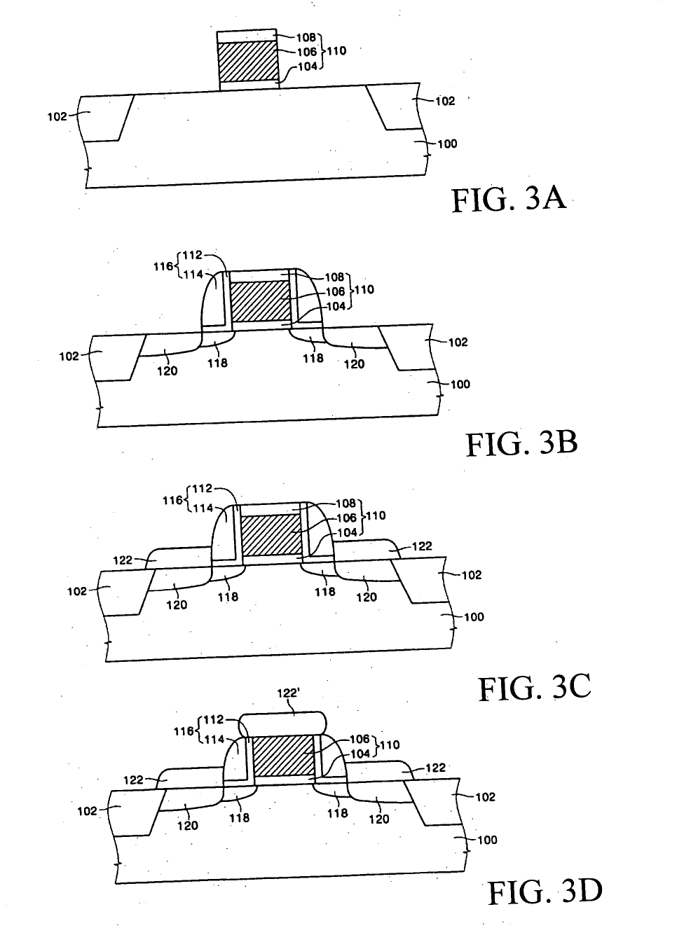

An example embodiment of a semiconductor fabrication process is illustrated in FIGS. 3A-3D. As illustrated in FIG. 3A, a semiconductor substrate 100, typically comprising silicon, silicon/germanium, silicon carbide or germanium, is processed to form shallow trench isolation (STI) structures 102, thereby defining active regions on the surface of the semiconductor substrate. A gate structure or pattern 110 is then formed in the active region. The gate structure 110 will typically include a dielectric or gate oxide layer 104 formed directly on the surface of the substrate, a gate electrode 106, typically a doped polysilicon or amorphous silicon layer arid, in some instances, silicide or salicide layers (not shown) for reducing the resistance of the gate electrode, and, optionally, a capping layer 108, for example silicon nitride, for protecting at least the upper surface of the gate electrode.

As illustrated in FIG. 3B, the gate structure 110 may be used as an implant mask for an initial source/drain implant, sometimes referred to as a lightly-doped drain or LDD implant during which a lightly doped region 118 is formed in the upper portions of the exposed semiconductor substrate 100. After the LDD formation is completed, a gate spacer structure 116 may be formed adjacent the sidewalls of the gate structure 110 by, for example, depositing or forming a conformal oxide layer followed by a conformal nitride layer. These layers are then etched back to form an inner oxide spacer 112 and an outer nitride spacer 114 that cooperate to form the gate spacer 116.

Once the gate spacer 116 has been formed, the composite structure including the gate structure 110 and the gate spacer can be used as an implant mask for the main source/drain implant during which a more heavily doped or deep source/drain region 120 is formed in the upper portions of the exposed semiconductor substrate 100. As a result of the gate spacer 116, the source/drain region 120 is offset from the edges of the gate structure 110. Although, as illustrated, the source/drain region 120 is formed in the semiconductor substrate, the source/drain region may be formed at least partially in or through an epitaxial region or layer (not shown) previously formed on the semiconductor substrate.

As illustrated in FIG. 3C, typically after the source/drain regions 118, 120 have been established, epitaxial regions 122 are grown on the exposed semiconductor surfaces of the semiconductor substrate 100. As detailed above, an example embodiment of a method used to form or grow the epitaxial regions 122 will include the steps of precleaning the semiconductor substrate to remove the majority of any contaminants present from the exposed substrate surfaces and the remaining surfaces present on the semiconductor substrate. Step 3 of FIG. 1.

The precleaned semiconductor substrate 100 is then positioned within a reactor chamber, step 5 of FIG. 1, and subjected to an in-situ cleaning process, steps 7-15 of FIG. 1, to remove residual contamination, particularly “native” oxides that have formed on the exposed semiconductor surfaces between the completion of the precleaning process and the establishing of a non-oxidizing ambient and/or vacuum condition within the reactor chamber. As detailed above, example cleaning processes according to the invention utilize both lower temperatures and, if H₂ is utilized, significantly lower H₂ flows, than those that would typically be employed during a conventional H₂ bake. It is anticipated that suitable cleaning of the exposed semiconductor surfaces can be achieved by maintaining the semiconductor substrate under a vacuum of about 50 mTorr or less, for example about 0.1 mTorr, for a period of about 30 to 180 seconds, for example 60 seconds, at a temperature of about 650° C. to 750° C., for example 700° C.

As will be appreciated by those skilled in the art, process variables such as, for example, the relative proportion of the exposed semiconductor surface area on the semiconductor substrate, the precleaning processes and the manner in which the semiconductor substrate was handled between the precleaning process and the initiation of the in-situ cleaning process, the volume of the reactor chamber and the particular conditions utilized for the in-situ cleaning process will each tend to affect the duration required to achieve sufficient cleaning to some extent. For example, on equipment used in the evaluation of the disclosed method, a suitable carrier gas flow may correspond to a flow rate of no more than about 500 sccm (standard cubic centimeters per minute).

Once the cleaning process has been completed, the conditions within the reactor and the condition, particularly the temperature, of the semiconductor substrate 100 is configured for growing an epitaxial layer 122 on the exposed semiconductor surfaces of the semiconductor substrate. Depending on the growth conditions and the exposed semiconductor surfaces, the epitaxial layer 122 may be grown as a single crystal semiconductor region corresponding to the crystalline orientation of the exposed semiconductor surface, a polycrystalline region, an amorphous region or a combination thereof. It is anticipated that suitable epitaxial regions may be grown using a combination of a source gas, for example SiH₂Cl₂ and/or GeH₂Cl₂, a carrier gas, for example H₂, and an etchant gas, for example HCl, with a substrate temperature of about 750° C. to 810° C., for example 780° C. As will be appreciated by those skilled in the art, process variables including, for example, the relative proportion of the exposed semiconductor surface area, the partial pressures of and compositions of the various gases, the target thickness of the epitaxial regions process and the initiation of the in-situ cleaning process and the particular conditions utilized for the in-situ cleaning process will all affect the duration required to achieve sufficient cleaning to some extent.

As illustrated in FIG. 3C, if a combination of a capping layer 108 and/or gate spacer structures 116 cooperate to enclose the gate electrode 106, the epitaxial regions will generally be limited to the exposed semiconductor surfaces and surfaces immediately adjacent the exposed surfaces. Conversely, as illustrated in FIG. 3D, if the gate structure and/or gate spacer structures are removed or modified to expose silicon surfaces other than those found in the source/drain regions of the semiconductor substrate, additional epitaxial regions 122′ will grow on the exposed surfaces of the gate electrode. Because the additional epitaxial regions 122′ will be grown from polycrystalline regions, in most instances the resulting semiconductor regions will not exhibit a single crystal orientation but will instead tend to grow as polycrystalline or amorphous regions depending on the growth conditions.

As with the underlying semiconductor substrate material, the epitaxial regions formed on the exposed semiconductor surfaces (and possibly additional exposed regions of the gate electrode) may constitute a variety of compositions including substantially pure silicon (Si), germanium (Ge), silicon/germanium (SiₓGe₁₋ₓ), and/or silicon carbide (SiₓC₁₋ₓ) as well as other secondary, tertiary and quaternary semiconductor materials. The epitaxial semiconductor layers and/or structures formed by the example process detailed above may be doped during their formation by introducing a dopant species, typically boron, phosphorous or antimony, by adding one or more suitable source gases to the reactor chamber ambient. Alternatively, the epitaxial regions may be selectively doped in a subsequent diffusion or implant process (not shown).

Once the formation of the epitaxial region(s) has been completed, the reactor chamber will typically be subjected to a second purging step, step 19 of FIG. 1, during which hydrogen gas and/or an inert gas or a mixture thereof is introduced into the reaction chamber. This second purging step will typically be maintained until the temperature of the semiconductor substrate 100 has been reduced to a level that will not tend to produce undue oxidation and/or is suitable for removal from the reaction chamber into an unload assembly.

### COMPARATIVE EXAMPLES

A series of transistors were prepared by processing substantially identically prepared silicon substrates according to three different epitaxial,processes as detailed below in TABLE 1:

TABLE 1

| Parameter | | Sample 1 | Sample 2 | Sample 3 |
|---|---|---|---|---|
| Substrate | | Single Crystal Si | | |
| Gate Dielectric | | SiON | | |
| Gate Electrode | | n-type polysilicon | | |
| LDD Species/Dose | | Arsenic/4 × 10¹⁴ atoms/cm² | | |
| Preclean Etchant | | HF | | |
| In-situ Clean | Reaction Gas | vacuum | H₂ | H₂ |
| | Temperature | 700 | 850 | 850 |
| | (° C.) | | | |
| | Pressure | 10-4 Torr | 5 Torr | 5 Torr |
| | Time | 60 | 60 | 60 |

| | | |
|---|---|---|
| Epitaxial Growth | Source Gas | SiH₂Cl₂ |
| | Etching Gas | HCl |
| | Transfer Gas | H₂ |
| | Temperature | 780 |
| | (° C.) | |

| | |
|---|---|
| S/D Implant | Arsenic/4 × 10¹⁵ atoms/cm² |
| Species/Dose | |

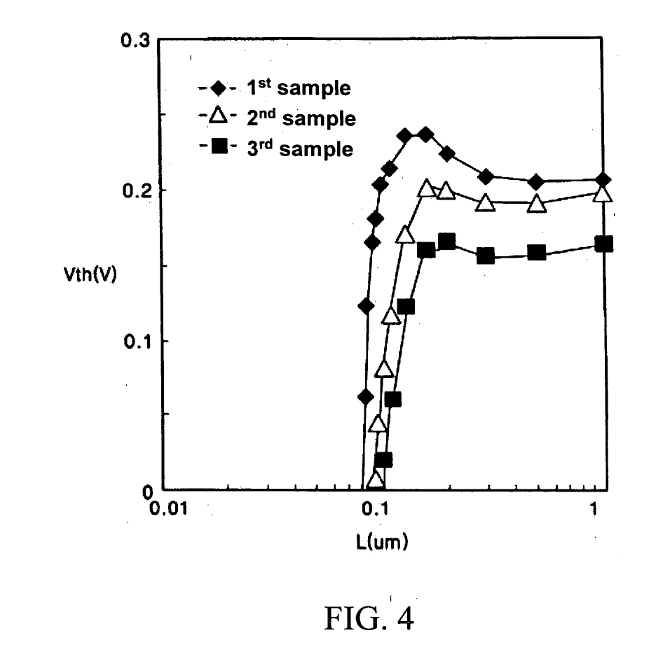

After the differing epitaxial processes were completed, the silicon substrates were subjected to the remainder of the device fabrication processing to produce transistors suitable for testing. The results of this testing, particularly with respect to the relationship between channel length in microns (μm) and the threshold voltage (Vₜₕ) is reflected in FIG. 4. As reflected in the comparative data, the example process corresponding to an embodiment of the invention used in processing Sample 1 produced transistors having both a higher average threshold voltage and a tighter channel length distribution. Both the Sample 2 and Sample 3 transistors reflected reduced threshold voltages and wider channel length distributions. Without being bound by any particular theory, it is suspected that the higher thermal budget imposed by the conventional hydrogen bake processes at 850° C., as opposed to the exemplary 700° C. employed in Sample 1, resulted in additional diffusion of the LDD dopant, thereby tending to reduce the effective channel length and the threshold voltage.

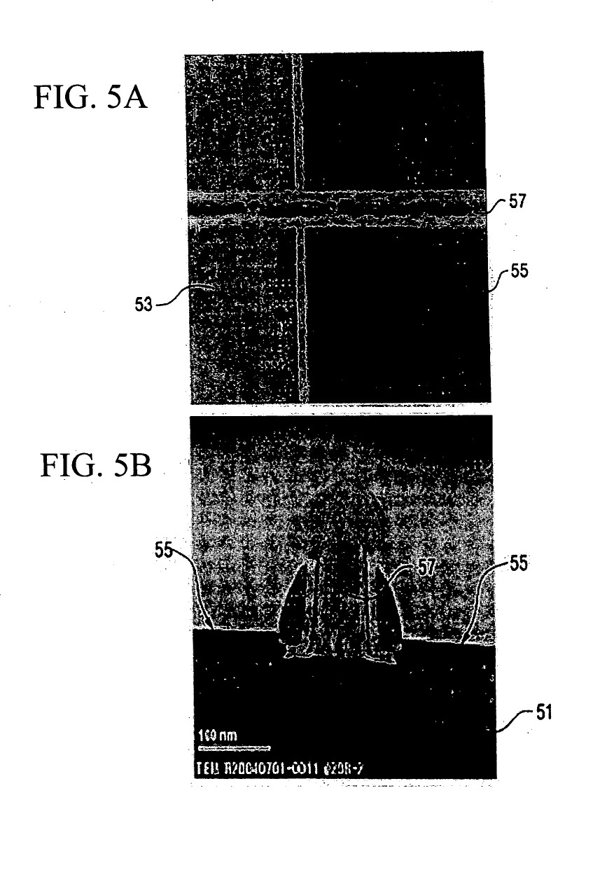

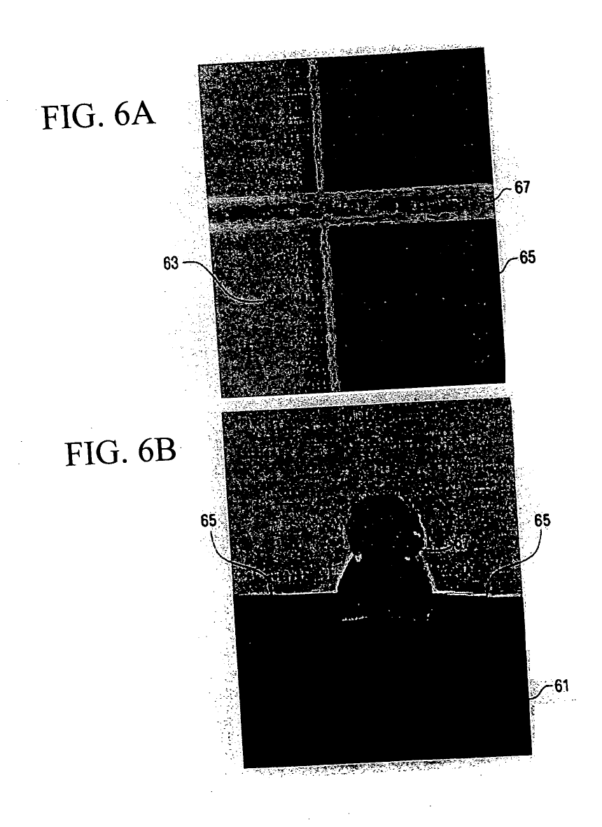

Representative NMOS and PMOS transistors manufactured using an in-situ cleaning process according to an example embodiment of the invention were inspected using both top or plan view electron microscopy scanning (SEM) images, FIGS. 5A and 6A, illustrating a portion of the gate structure extending across both an active region and an adjacent shallow trench isolation region. Also provided are cross-sectional transmission electron microscopy (TEM) images, FIGS. 5B and 6B, illustrating the respective gate electrode structures. The results of these examinations with respect to the NMOS transistor are reflected in the images provided in FIGS. 5A and 5B. For ease of reference, various regions of the NMOS transistor are identified with reference numerals including, for example, the silicon substrate 51, the STI structure 53, the epitaxial layer 55 and the gate electrode structure 57. Similarly, the results of these examinations with respect to the PMOS transistor are reflected in the images provided in FIGS. 6A and 6B. Again, for ease of reference, various regions of the PMOS transistor are identified with reference numerals including, for example, the silicon substrate 61, the STI structure 63, the epitaxial layer 65 and the gate electrode structure 67. As can be observed in the images reproduced as FIGS. 5A-6B, the interface between the epitaxial layers 55, 65 and the underlying silicon substrate regions 51, 61, is very clean and smooth, indicating that substantially no oxygen was present on the surface of the substrate as the epitaxial growth was initiated.

Although the invention has been described in connection with certain exemplary embodiments, it will be evident to those of ordinary skill in the art that many alternatives, modifications, and variations may be made to the disclosed methods in a manner consistent with the detailed description provided above. Also, it will be apparent to those of ordinary skill in the art that certain aspects of the various disclosed example embodiments could be used in combination with aspects of any of the other disclosed embodiments or their alternatives to produce additional, but not herein illustrated, embodiments incorporating the claimed invention but more closely adapted for an intended use or performance requirements. Accordingly, it is intended that all such alternatives, modifications and variations that fall within the spirit of the invention are encompassed within the scope of the appended claims.

We claim:

1. A method of fabricating an epitaxial layer comprising, in order:
placing a substrate having an exposed semiconductor surface into a reaction chamber;
establishing a cleaning pressure in the reaction chamber and heating the substrate to a cleaning temperature to establish a cleaning condition under which oxide present on the exposed semiconductor surface will decompose and release oxygen;
maintaining the cleaning condition for a cleaning period sufficient to remove the oxide, thereby forming a clean semiconductor surface;
forming an epitaxial layer on the clean semiconductor surface; and
removing the substrate from the reaction chamber.

2. The method of fabricating an epitaxial layer according to claim 1, wherein:
the cleaning pressure is less than about 1 mTorr; and
the cleaning temperature is less than about 800° C.

3. The method of fabricating an epitaxial layer according to claim 1, further comprising:
precleaning the exposed semiconductor surface before placing the substrate in the reaction chamber.

4. The method of fabricating an epitaxial layer according to claim 1, wherein:
the cleaning pressure is less than about 1 mTorr;
the cleaning temperature is from about 500° C. to about 750° C.; and
the cleaning period is less than about 200 seconds.

5. The method of fabricating an epitaxial layer according to claim 1, wherein:
the cleaning pressure is less than about 0.1 mTorr,
the cleaning temperature is from about 730° C. to about 790° C.; and
the cleaning period is less than about 120 seconds.

6. The method of fabricating an epitaxial layer according to claim 1, further comprising:
injecting a carrier gas into the reaction chamber during the cleaning period.

7. The method of fabricating an epitaxial layer according to claim 6, wherein:
the carrier gas is selected from a group consisting of hydrogen, argon, neon, krypton and mixtures thereof.

8. The method of fabricating an epitaxial layer according to claim 7, wherein:
the cleaning pressure is less than about 50 mTorr;
the cleaning temperature is less than about 800° C.; and
the cleaning period is less than about 200 seconds.

9. The method of fabricating an epitaxial layer according to claim 6, wherein:
the carrier gas is injected at a flowrate sufficient to maintain oxygen gaswithin the reaction chamber at less than 50% of a saturation amount under the cleaning condition.

10. The method of fabricating an epitaxial layer according to claim 6, wherein:
the carrier gas is injected at a flowrate sufficient to maintain oxygen gas within the reaction chamber at less than 10% of a saturation amount under the cleaning condition.

11. The method of fabricating an epitaxial layer according to claim 9, wherein:
the carrier gas is injected at a flowrate of no more than about 500 sccm.

12. The method of fabricating an epitaxial layer according to claim 1, wherein:
the exposed semiconductor surface is selected from a group consisting of silicon, germanium, binary semiconductor materials, tertiary semiconductor materials, quaternary semiconductor materials and combinations thereof.

13. The method of fabricating an epitaxial layer according to claim 1, further comprising:
monitoring a condition within the reaction chamber during the cleaning period to determine an oxide removal rate; and
terminating the cleaning period when the oxide removal rate falls below a removal rate lower limit.

14. The method of fabricating an epitaxial layer according to claim 1, further comprising:
monitoring a condition within the reaction chamber during the cleaning period to determine an oxide removal rate; and
terminating the cleaning period when the oxide removal rate has been below a removal rate lower limit for a finishing period.

15. The method of fabricating an epitaxial layer according to claim 1, further comprising:
maintaining the substrate under a cool down condition between forming the epitaxial layer and removing the substrate from the reaction chamber, the cool down condition being sufficient to suppress oxidation of the epitaxial layer.

16. The method of fabricating an epitaxial layer according to claim 15, further comprising:
injecting a cool down gas into the reaction chamber between forming the epitaxial layer and removing the substrate from the reaction chamber.

17. The method of fabricating an epitaxial layer according to claim 16, wherein:
the cool down gas is selected from a group consisting of hydrogen, argon, neon, krypton and mixtures thereof.

18. The method of fabricating an epitaxial layer according to claim 1, further comprising:
maintaining the substrate under a ramp up ambient after placing the substrate in the reaction chamber and before reaching the cleaning condition, the ramp up ambient being sufficient to suppress oxidation of the exposed semiconductor surface.

19. The method of fabricating an epitaxial layer according to claim 18, further comprising:
injecting a ramp up gas into the reaction chamber after placing the substrate in the reaction chamber and until the cleaning condition is reached.

20. The method of fabricating an epitaxial layer according to claim 19, wherein:
the ramp up gas is selected from a group consisting of hydrogen, argon, neon, krypton and mixtures thereof.

21. A method of fabricating a semiconductor device comprising:
processing a semiconductor substrate to form intermediate device structures having exposed semiconductor surfaces;
placing the intermediate device structures into a reaction chamber;
establishing a cleaning pressure in the reaction chamber and heating the intermediate device structures to a cleaning temperature to establish a cleaning condition under which oxide present on the exposed semiconductor surfaces will decompose and release oxygen gas;
maintaining the cleaning condition for a cleaning period sufficient to remove the oxygen, thereby forming clean semiconductor surfaces;
forming an epitaxial layer on the clean semiconductor surfaces; and
removing the semiconductor substrate from the reaction chamber:

22. The method of fabricating a semiconductor device according to claim 21, wherein:.
the exposed semiconductor surfaces are source/drain regions.

23. The method of fabricating a semiconductor device according to claim 21, wherein:
the exposed semiconductor surfaces are source/drain regions and a gate electrode surface.

24. The method of fabricating a semiconductor device according to claim 21, wherein:
the epitaxial layer has an epitaxial layer structure selected from a group consisting of single crystal semiconductor structures, polycrystalline semiconductor structures, amorphous semiconductor structures and combinations thereof.

25. The method of fabricating a semiconductor device according to claim 24, wherein:
only one type of epitaxial layer structure is formed on each exposed semiconductor surface.

26. The method of fabricating a semiconductor device according to claim 24, wherein processing the semiconductor substrate to form intermediate device structures having exposed semiconductor surfaces further comprises:
defining active semiconductor regions on the semiconductor substrate;
forming gate stack structures on a portion of a surface of active regions; and
exposing a second portion of the surface of the active regions.

27. The method of fabricating a semiconductor device according to claim 24, wherein processing the semiconductor substrate to form intermediate device structures having exposed semiconductor surfaces further comprises:
defining active semiconductor regions on the semiconductor substrate;
forming gate stack structures on a portion of a surface of active regions; and
exposing a second portion of the surface of the active regions and a semiconductor surface on the gate stack structures.

28. A method of fabricating an epitaxial layer comprising, in order:
placing a substrate having an exposed semiconductor surface into a reaction chamber;
establishing a cleaning pressure in the reaction chamber and heating the substrate to a cleaning temperature under a cleaning ambient to establish a cleaning condition under which a major portion of oxide present on the exposed semiconductor surface will be removed by decomposition and a minor portion of the oxide present on the exposed semiconductor surface will be converted lo silicon by a reduction reaction;
maintaining the cleaning condition for a cleaning period sufficient to remove the oxide, thereby forming a clean semiconductor surface;
forming an epitaxial layer on the clean semiconductor surface; and
removing the substrate from the reaction chamber.

29. A method of fabricating an epitaxial layer comprising, in order:
placing a substrate having an exposed semiconductor surface into a reaction chamber;
establishing a first cleaning pressure in the reaction chamber and heating the substrate to a first cleaning temperature under a first cleaning ambient to establish a first cleaning condition under which a major portion of oxide present on the exposed semiconductor surface will be removed by decomposition;
establishing a second cleaning pressure in the reaction chamber and heating the substrate to a second cleaning temperature under a second cleaning ambient to establish a second cleaning condition under which a minor portion of oxide present on the exposed semiconductor surface will be converted to silicon by a reduction reaction;
maintaining the second cleaning condition for a second cleaning period sufficient to convert the minor portion of the oxide, thereby forming a clean semiconductor surface;
forming an epitaxial layer on the clean semiconductor surface; and
removing the substrate from the reaction chamber.

30. A method of cleaning an exposed semiconductor surface comprising:
establishing a cleaning pressure in a reaction chamber and heating a semiconductor substrate to a cleaning temperature of under a cleaning ambient to establish a cleaning condition under which a major portion of oxide present on the exposed semiconductor surface will be removed by decomposition.

31. The method of cleaning an exposed semiconductor surface according to claim 30, further comprising:
removing a minor portion of the oxide present on the exposed semiconductor surface by a reduction reaction.

32. The method of cleaning an exposed semiconductor surface according to claim 30, wherein:
the cleaning temperature is no more than about 800° C.

33. The method of cleaning an exposed semiconductor surface according to claim 30, further including.
maintaining a cleaning pressure within the reaction chamber whereby the partial pressure of oxygen gas vapor is no more than 50% of the equilibrium partial pressure at the cleaning temperature.

34. The method of cleaning an exposed semiconductor surface according to claim 32, further including:
maintaining a cleaning pressure within the reaction chamber whereby the partial pressure of oxygen gas is no more than about 50% of the equilibrium partial pressure at the cleaning temperature.
